(19) United States
(12) Patent Application Publication
(10) Pub. No.: US 2013/0009720 A1
(43) Pub. Date: Jan. 10, 2013

(54) WIDE BANDWIDTH AUTOMATIC TUNING CIRCUIT

(75) Inventors: Carson R. White, Agoura Hills, CA (US); Joseph S. Colburn, Malibu, CA (US); Michael W. Yung, Los Angeles, CA (US); Donald A. Hitko, Grover Beach, CA (US)

(73) Assignee: HRL LABORATORIES, LLC, Malibu, CA (US)

(21) Appl. No.: 13/177,479

(22) Filed: Jul. 6, 2011

(51) Int. Cl. H03H 7/40; H03H 7/38

(52) U.S. Cl. 333/17.3; 333/32

(57) ABSTRACT

An automatic tuning circuit for matching an antenna to a radio receiver. The automatic tuning circuit includes a tunable non-Foster circuit for coupling the receiver and the antenna; and sensing and feedback circuits for sensing the combined capacitance of the tunable non-Foster circuit and the antenna and for tuning the tunable non-Foster circuit to automatically minimize the combined capacitance of the tunable non-Foster circuit and the antenna.

### CROSS REFERENCE TO RELATED APPLICATIONS

This application is related to U.S. Provisional patent application Ser. No. ______ filed on the same date as this application and entitled “Differential negative impedance converters and inverters with tunable conversion ratios” (Attorney Docket 626408-4), the disclosure of which is hereby incorporated herein by reference.

### TECHNICAL FIELD

This invention relates to a wide bandwidth automatic tuning circuit. Automatic tuning circuits are used to connect a transmitter and/or a receiver to an antenna with a better impedance match than if the transmitter and/or the receiver were directly connected to the antenna.

### BACKGROUND

The useable radio spectrum is limited and traditionally the available spectrum has been licensed to particular users or groups of users by governmental agencies, such as the Federal Communications Commission in the United States. This licensing paradigm may be on the cusp of change. In the article “The End of Spectrum Scarcity” published by IEEE Spectrum, the authors note that while some available spectrum is congested, much of it is underutilized. They predict a future where spectrum is cooperatively shared and where smart antennas will adaptively lock onto a directional signal and when used in a transmission mode, operate directionally as opposed to omnidirectionally.

In terms of sharing spectrum, one way of doing so is by the use of spread spectrum technologies. Ultra-wideband (UWB) technology uses ultra wide bandwidths (for example, in excess of 500 MHz) to transmit information which in theory at least should not interfere with existing narrow band licensees (whose narrow band transmissions have bandwidths in the 0.5 to 15 KHz range).

Another spectrum sharing technique which is currently under discussion is cognitive radio which envisions using underutilized portions of the radio spectrum on an as needed basis. Cognitive radio can adapt to using different parts or portions of the radio spectrum when those parts or portions are not being actively used by another user.

Both UWB and cognitive radio have a need for widebanded communication equipment, with bandwidths significantly wider than found in most conventional radio equipment today. It is believed that future radio equipment will operate over much wider bandwidths than typical radio equipment does today.

It is well known that the performance of electrically-small antennas (ESAs) is limited when using traditional (i.e. passive) matching networks. Specifically, ESAs have high quality factor, leading to a tradeoff between bandwidth and efficiency. The most common definition of a ESA is an antenna whose maximum dimension (of an active element) is no more than ½π of a wavelength of the frequencies at which the antenna is expected to operate. So, for a dipole with a length of λ/2π, a loop with a diameter of λ/2π, or a patch with a diagonal dimension of λ/2π would be considered electrically small.

ESAs are very popular. They allow the antennas to be small. But due to their smallness, they can be very narrow banded.

The conventional way of dealing with an antenna which is used with a receiver and/or a transmitter with operates over a frequency band, and particularly where the antenna is mis-sized compared the frequency to be utilized, is to use an antenna matching network. Antenna matching networks operate ideally at a particular frequency and therefore if the transmitter or receiver changes frequency, the mating network should normally be retuned accordingly.

A passive adaptive antenna match is taught by U.S. Pat. No. 4,234,960. The antenna in U.S. Pat. No. 4,234,960 is resonated by a passive tuning circuit that is adjusted using a motor. A phase detector senses the presence of reactance and drives the motor until the reactance has been eliminated. This has two disadvantages: 1) the bandwidth is narrow due to the use of a passive tuning circuit, which necessitates the use of coarse (frequency sensing) and fine adjust, and 2) the motor driven tuning is slower than electronic tuning.

A “RF-MEMS based adaptive antenna matching module” taught by A. V. Bezooijen, et al., 2007 IEEE RFIC Symposium, resonates the antenna with a MEMS switched capacitor array. A phase detector senses the phase of the input impedance and steps the capacitance of the matching circuit either up or down by 1 increment depending on the sign of the phase. Disadvantages: 1) a positive capacitance does not resonate a monopole-type ESA 2) passive matching circuit results in narrow-band solution for ESA; and 3) digital tuning gives limited number of states.

Non-Foster matching networks overcome the limitations of passive circuits by using active circuits to synthesize negative capacitors and negative inductors in the antenna matching networks. When placed correctly, these circuits can directly subtract the from the antenna's reactance. For example, a 6″ monopole antenna has a reactance that may be approximated by a 3 pF capacitor at frequencies well below resonance. When combined with a −3.1 pF non-Foster capacitor, the net reactance is given by a 93 pF capacitor (using Eqn. (3) below), which is a 30 times improvement since the reactance is reduced by 30 times.

There are two related problems with this approach that need to be addresses before non-Foster matching is robust enough to be deployed in products: stability and accuracy. Negative capacitance is achieved using feedback circuits whose stability depends on both the internal circuit parameters and the load impedance; instability leads to either oscillation (i.e. emission of a periodic waveform from the circuit) or latchup. Unfortunately, the optimal impedance match typically occurs near the point where the stability margin goes to zero. Since non-Foster matching involves the subtraction of large reactances, high accuracy (tolerance ˜1/Q) is needed to ensure both stability and optimal antenna efficiency. Consider the example just given, where the 6″ monopole antenna, which has a reactance that may be approximated by a 3 pF capacitor at frequencies well below resonance, is combined with a −3.1 pF non-Foster capacitor. The match is theoretically better with a −3.05 pF non-Foster capacitor, but if the net capacitance goes negative (see Eqn. (3)), then the match is unstable. There will probably always be manufacturing tolerances in making both antennas and circuits devices, but as accuracy improves the better the match network can be designed using a non-Foster capacitor. But accuracy and stability are related since the accuracy by which components can be manufactured will impact the likelihood of an unstable situation arising by reason of the combined antenna impedance and match network impedance being negative.

Component and manufacturing tolerances, as well as temperature and environmental loading effects, suggest that even a 10% error may be challenging to achieve using prior art non-Foster circuits.

Having a robust non-Foster automatic tuning circuit for coupling a transmitter and/or a receiver to an antenna, especially a ESA, would be useful for use (i) in automobiles since it would allow the antenna design to be further reduced in size which is turn can lead to more aesthetic automobile designs and in vehicles (automobiles, trucks, trains, planes, ship and boats) a smaller antenna is likely to reduce drag and thereby increase efficiency. There are many.many more applications for this technology, such as the cognitive and UWB radios mentioned above.

### BRIEF DESCRIPTION OF THE INVENTION

In one aspect the present invention provides an automatic tuning circuit for matching an antenna to a radio receiver, the automatic tuning circuit comprising: a tunable non-Foster circuit for coupling the receiver and the antenna; and sensing and feedback circuits for sensing the combined reactance of the tunable non-Foster circuit and the antenna and for tuning the tunable non-Foster circuit to automatically minimize the combined reactance of the tunable non-Foster circuit and the antenna.

In another aspect the present invention provides a tuning circuit for matching an antenna to a variable frequency oscillator, the automatic tuning circuit comprising: a tunable non-Foster circuit for coupling the variable frequency oscillator and the antenna; and sensing and feedback circuits for sensing the combined reactance of the tunable non-Foster circuit and the antenna and for tuning the tunable non-Foster circuit to minimize the combined reactance of the tunable non-Foster circuit and the antenna.

A method of matching an antenna to a radio receiver, the method comprising: coupling a tunable non-Foster circuit between the receiver and the antenna, the receiver and the antenna having a combined reactance; sensing the combined reactance of the tunable non-Foster circuit and the antenna in a sensing circuit; and tuning the tunable non-Foster circuit to minimize the combined reactance of the tunable non-Foster circuit and the antenna as sensed by the sensing circuit.

### BRIEF DESCRIPTION OF THE DRAWINGS

FIG. 1 is a schematic block diagram of the auto-tuning non-Foster matching circuit.

FIG. 2 is a schematic diagram of an exemplary tunable non-Foster negative capacitor. The negative impedance converter transforms the model capacitor, Cm, to a negative capacitance, −Cm. The variable capacitance, Cvar, provides tunability.

FIG. 3 depicts a simulation setup for a SPICE simulation. The circuits of FIGS. 1 and 2 has been simulated using an ideal non-Foster negative capacitor and an ideal double balanced mixer.

FIG. 4 depicts the time domain results of the SPICE simulation of FIG. 3. The circuit converges to optimal efficiency in 35 microseconds. The efficiency improvement is more than 10 dB.

### DETAILED DESCRIPTION

This invention provides an automatically-tuning non-Foster matching circuit, which automatically drives the input reactance (Zᵢₙ) to zero at one frequency. It is well known that the performance of electrically-small antennas (ESAs) is limited when using traditional (i.e. passive) matching networks due to their high antenna Q. Non-Foster Circuits (NFCs) can reduce the antenna reactance by orders of magnitude by synthesizing negative capacitance or negative inductance, which are then placed in series (when using negative capacitance) or parallel (when using negative inductance) such that they cancel the antenna reactance over a broad bandwidth. A high degree of accuracy is desired to effectively cancel large antenna reactances. In addition, NFCs are conditionally stable, and typically have very small stability margin at the point where they best cancel the antenna reactance. Therefore it is critical to design and control the NFC circuit very accurately in order to optimize performance while keeping the circuit stable.

Considering a series R-L-C circuit, the input impedance is given by Eqn (1) below:

Zin=R+sL+1/sC. Eqn. (1)

where R is the resistance, L is the inductance, C is the capacitance, s=jω, ω is the radian frequency, and j=sqrt(−1). It has been shown in the literature that the system is unstable if Zin has either poles or zeros in the Right Half Plane (RHP); Zin has no poles, and has zeros given by Eqn. (2) below:

$${s}_{z} = 0.5 ( - \frac{R}{L} \pm \sqrt{{( \frac{R}{L} )}^{2} - \frac{4}{LC}} ) . \qquad Eqn . ( 2 )$$

It can be seen that when R and L are >0, there is a RHP solution for s_{z} if and only if C<0. Therefore, the net capacitance must be positive for stability. In addition, the circuit resonates when at the frequency given by fₒ=½π\sqrt{LC} when C is positive. With non-Foster matching, the negative capacitance produced by the NFC, −C_{NF}, is connected in series with the positive capacitance of the antenna, Cₐ, producing a net capacitance given by Eqn. (3) below:

$$C = \frac{- {C}_{a} {C}_{NF}}{{C}_{a} - {C}_{NF}} . \qquad Eqn . ( 3 )$$

Therefore the circuit may be tuned to resonate at f, while remaining stable by starting with −C_{NF} comfortably below −C, and tuning −C_{NF} to approach −Cₐ. In theory, −C_{NF} can equal −Cₐ (so that perfect cancellation occurs), but if the combination of the two capacitances is a negative value, the condition is unstable. So in practice −C_{NF} is preferably tuned to only to approach −C, with the difference being an amount which accounts for manufacturing tolerances.

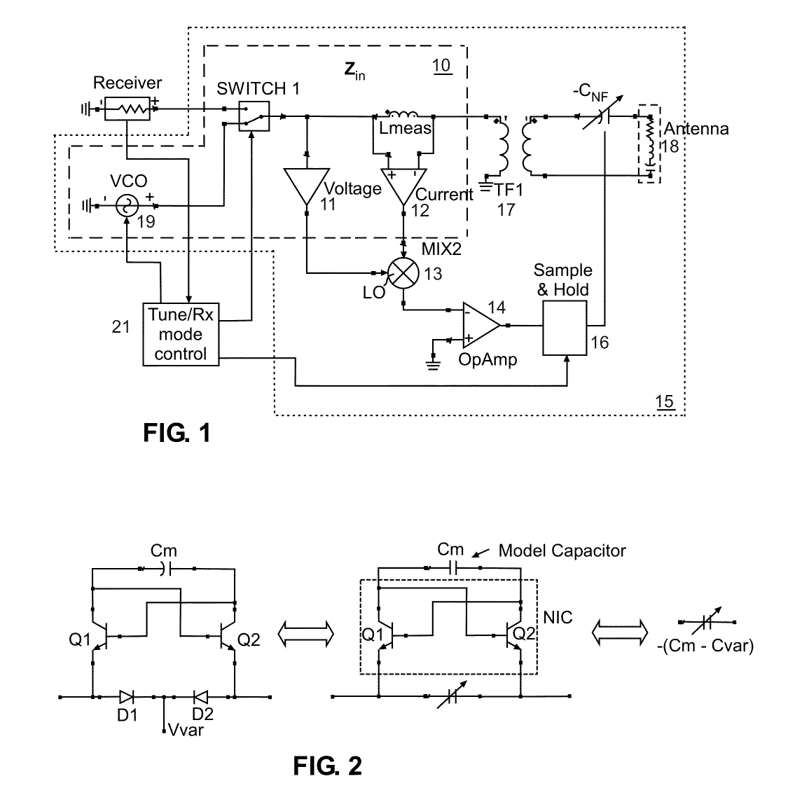

The circuit of FIG. 1 includes a tunable negative (i.e. non-Foster) capacitor C_{NF}, sensing circuitry 10 for sensing the reactance in real-time, and an associated feedback loop 15 that automatically drives the input reactance Zᵢₙ to zero. In this embodiment, the sensing circuitry is also considered part of the feedback loop.

The sensing circuit 10 includes a variable frequency oscillator 19 (which may be implemented by a voltage controlled oscillator or VCO) which injects a signal at the desired frequency of operation via a switch (SWITCH1); this signal may either a transmit signal for transmitter applications, or a low output power oscillator that is switched onto the signal path (via SWITCH1) in order to measure the reactance at Zᵢₙ for receive applications. The input voltage is directly sensed using a single-ended buffer 11 (which may be implemented as an Operational Amplifier (OpAmp)), and the input current is sensed by connecting a differential buffer 12 (which may be implemented as an OpAmp) across a small inductor, Lₘₑₐₛ, that is inserted specifically for the reactance measurement. The small inductor may only impose one or two ohms of reactance and its value is a matter of design choice depending on the sensitivity desired. The voltage across Lₘₑₐₛ is proportional to the input current, but shifted by 90°. Therefore, multiplying the voltage and current signals using a double balanced mixer 13 (keeping only the DC output, using a low-pass filter if need be), directly results in a reactance measurement. The double balanced mixer is considered part of the feedback circuit in this detailed description, but it can also be considered part of the sensing circuit 10 as well.

A double balanced mixer 13 should be utilized in order to preserve the sign of the reactance. This voltage is then applied to an OpAmp 14, which produces the tuning voltage for the tunable negative capacitor such that the input reactance (Zᵢₙ) is driven to zero.

This circuit may be used in two modes: continuous tuning and periodic tuning. Continuous tuning is useful for transmit antenna matching. In this mode, where the signal is constantly applied at a center frequency f₀, the feedback loop is always on and no sample and hold circuit 16 is needed and no mode control switch or circuit 21 is needed. The periodic mode is useful for receive antenna matching. In the periodic mode, the circuit is switched at SWITCH1 (in response to the state of mode control switch or circuit 21) between the receiver and the oscillator 19. The mode control switch or circuit 21 has two states: a tuning state and a receive state. When the mode control switch or circuit 21 is in its tuning state, the oscillator 19 applies a signal in the sensing circuit 10 and the feedback circuit 15 drives the reactance to zero while the sample and hold circuit 16 samples the tuning voltage. When the mode control switch or circuit 21 is in its receive state, the circuit is switched at SWITCH1 to the receiver but the just determined tuning voltage is held constant by the sample and hold circuit 16. In the preferred embodiment, the circuit starts up with −C_{NF} comfortably below −Cₐ, and may be reset to that level at the beginning of each tuning state.

The balun or transformer 17 preferably couples the sensing circuit to the antenna 18 and the NFC (implemented as the negative capacitor −C_{NF} in this embodiment). Depending on the configuration of the antenna match, the NFC could instead be implemented as a negative inductor. Many antenna match circuits are known in the art which utilize variable capacitors and/or inductors, and selecting one of the variable capacitors or inductors in such circuits to be implemented as a negative reactance (instead of a traditional positive reactance) can have a profound impact on the bandwidth of the antenna match circuit.

The antenna 18 may be any sort of antenna, but if a ESA is utilized, then it is preferably either a dipole or a monopole antenna as those antenna types are frequently used of ESAs.

An exemplary tunable NFC is shown in FIG. 2 as three different representations of the same circuit. On the left hand side is a circuit with two varactor diodes which is electrically equivalent to the center presentation which shows a variable capacitor in place of the two varactor diodes. On the right hand side is the result (−(Cm−Cvar)). This circuit is based on Linvill's floating Negative Impedance Converter (NIC), but is an improvement there over and results in a tunable negative capacitance. A positive capacitance Cm is connected between the collectors of bipolar transistors Q1 and Q2. The input impedance looking into the emitters is given by −1/jωCm; therefore, the combination of Cm and the NIC is equivalent to a capacitor with value −Cm. A variable capacitor (in the center representation) with capacitance Cvar is connected between the emitters of Q1 and Q2; this combines with −Cm to give a tunable capacitance given by −(Cm−Cvar) between the two emitters. In embodiment on the left hand side, the variable capacitor is implemented by back-to-back reverse-biased varactor diodes D1 and D2, where the bias voltage from the sample and hold circuit 16 is applied to the Vvar node relative to the emitter voltage.

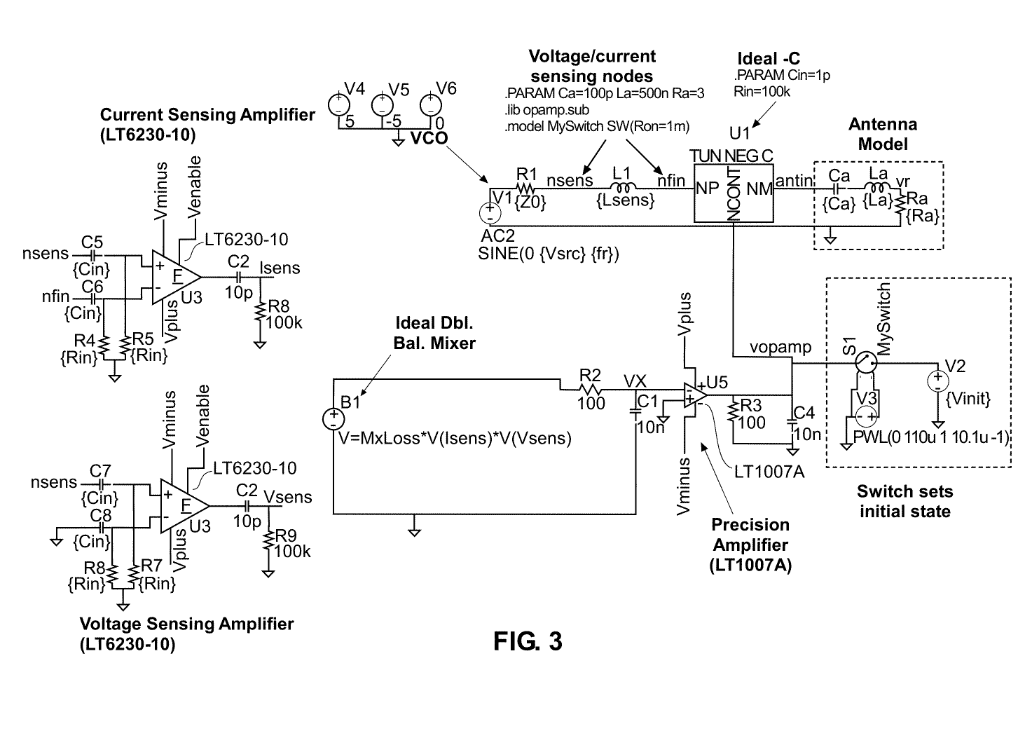

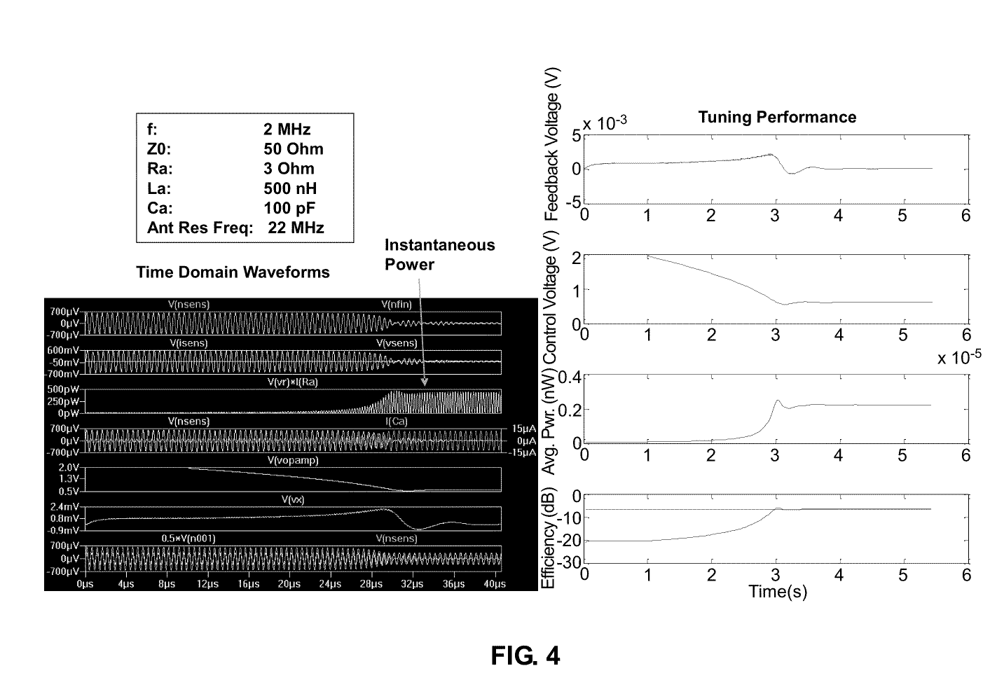

A SPICE simulation has been performed of the circuits of FIGS. 1 and 2, and the setup therefor is shown in FIG. 3. The antenna 18 is modeled as a series R-L-C circuit with values, and is tuned with an ideal voltage-controlled negative capacitor 19 whose capacitance in pF is given by −C=−80−35*Vc, where Vc is the control voltage (equal to Vvar in FIG. 2). Voltage source V2 and switch S1 set the initial bias state (−C=−150 pF), and the feedback loop is closed at 10 microseconds. The voltage and current sensing buffers are implemented with high-speed operational amplifiers, and the double-balanced mixer is implemented with a behavioral model assuming ideal multiplication and 6 dB insertion loss. The final element of the feedback loop is a precision operational amplifier to drive the reactance to zero. The simulation demonstrates convergence to the optimum efficiency (−6.7 dB) in 25 microseconds. The final non-Foster capacitance value is −C=−101 pF, which increases the total capacitance from 100 pF to 8.9 nF and resonates the antenna at 2 MHz.

In addition to doing a circuit simulation, a circuit in accordance with FIG. 1 has been built and tested. The test results are discussed in Appendix A to this application entitled “A Non-Foster-Enhanced Monopole Antenna”. In that embodiment, after testing, Cm was selected to be a 5.6 pF capacitor while Cvar should preferably have a tuning range of about 4-10 pF in that embodiment, so the diodes D1 and D2, being in series, should then having a tuning range of about 2-5 pF in that embodiment.

The circuits of FIG. 2 show one possible embodiment of a NFC to implement the negative capacitor −C_{NF}. Other NFC are depicted in the US Provisional patent application identified above which is incorporated herein by reference. In particular, the tunable NFC shown in FIG. 1(c) thereof could be used in place of the circuits of FIG. 2. Since the tunable NFC shown in FIG. 1(c) thereof is tunable as described therein, the addition of capacitor Cvar is not required at the negative impedance output thereof, but nevertheless the capacitor Cvar (preferably implemented as diodes D1 and D2) may be added negative impedance output thereof similarly to the modification to Linvall's circuit proposed by FIG. 2 hereof.

As is also mentioned in Appendix A, adding some resistance in series with Cm results in negative resistance at the output of the NFC which in turn adds gain.

Having described the invention in connection with certain embodiments thereof, modification will now suggest itself to those skilled in the art. As such, the invention is not to be limited to the disclosed embodiments except as is specifically required by the appended claims.

What is claimed is:

1. An automatic tuning circuit for matching an antenna to a radio receiver, the automatic tuning circuit comprising:
a tunable non-Foster circuit for coupling the receiver and the antenna; and
sensing and feedback circuits for sensing the combined reactance of the tunable non-Foster circuit and the antenna and for tuning the tunable non-Foster circuit to automatically minimize the combined reactance of the tunable non-Foster circuit and the antenna.

2. The automatic tuning circuit of claim 1 wherein the tunable non-Foster circuit comprises an otherwise non-tunable non-Foster circuit with a variable capacitance added across a negative impedance output of the otherwise non-tunable non-Foster circuit to thereby render the otherwise non-tunable non-Foster circuit tunable.

3. The automatic tuning circuit of claim 2 wherein the variable capacitance is supplied by reverse biased varactor diodes coupled in series with the negative impedance output of the otherwise non-tunable non-Foster circuit, a junction point between the series coupled varactor diodes providing a control input to the tunable non-Foster circuit.

4. The automatic tuning circuit of claim 3 wherein the sensing and feedback circuits comprise:
means for sensing an input impedance associated with the antenna and the tunable non-Foster circuit when a RF signal is applied to the antenna and the tunable non-Foster circuit via the means for sensing; and
an operational amplifier whose output is coupled to the control input of the tunable non-Foster circuit.

5. The automatic tuning circuit of claim 4 wherein the sensing and feedback circuits further comprise a sample and hold circuit coupled between said operational amplifier and said control input of the tunable non-Foster circuit.

6. The automatic tuning circuit of claim 1 wherein the sensing and feedback circuits comprise:
means for sensing an input impedance associated with the antenna and the tunable non-Foster circuit when a RF signal is applied to the antenna and the tunable non-Foster circuit via the means for sensing; and
an operational amplifier whose output is coupled to a control input of the tunable non-Foster circuit.

7. The automatic tuning circuit of claim 6 wherein the sensing and feedback circuits further comprise a sample and hold circuit coupled between said operational amplifier and said control input of the tunable non-Foster circuit.

8. The automatic tuning circuit of claim 1 wherein the tunable non-Foster circuit emulates a variable negative capacitor and wherein the antenna is a dipole or a monopole.

9. A tuning circuit for matching an antenna to a variable frequency oscillator, the automatic tuning circuit comprising:
a tunable non-Foster circuit for coupling the variable frequency oscillator and the antenna; and
sensing and feedback circuits for sensing the combined reactance of the tunable non-Foster circuit and the antenna and for tuning the tunable non-Foster circuit to minimize the combined reactance of the tunable non-Foster circuit and the antenna.

10. The tuning circuit of claim 9 wherein the tunable non-Foster circuit comprises an otherwise non-tunable non-Foster circuit with a variable reactance added across a negative impedance output of the otherwise non-tunable non-Foster circuit to thereby render the otherwise non-tunable non-Foster circuit tunable.

11. The tuning circuit of claim 10 wherein the variable reactance is supplied by reverse biased varactor diodes coupled in series with the negative impedance output of the otherwise non-tunable non-Foster circuit, a junction point between the series coupled varactor diodes providing a control input to the tunable non-Foster circuit.

12. The automatic tuning circuit of claim 11 wherein the sensing and feedback circuits comprise:
means for sensing an input impedance associated with the antenna and the tunable non-Foster circuit when a RF signal is applied to the antenna and the tunable non-Foster circuit via the means for sensing; and
an operational amplifier whose output is coupled to the control input of the tunable non-Foster circuit.

13. The automatic tuning circuit of claim 12 wherein the sensing and feedback circuits further comprise a sample and hold circuit coupled between said operational amplifier and said control input of the tunable non-Foster circuit.

14. The automatic tuning circuit of claim 9 wherein the sensing and feedback circuits comprise:
means for sensing an input impedance associated with the antenna and the tunable non-Foster circuit when a RF signal is applied to the antenna and the tunable non-Foster circuit via the means for sensing; and
an operational amplifier whose output is coupled to a control input of the tunable non-Foster circuit.

15. The automatic tuning circuit of claim 14 wherein the sensing and feedback circuits further comprise a sample and hold circuit coupled between said operational amplifier and said control input of the tunable non-Foster circuit.

16. The automatic tuning circuit of claim 9 wherein the tunable non-Foster circuit emulates a variable negative capacitor and wherein the antenna is a dipole or a monopole.

17. A method of matching an antenna to a radio receiver, the method comprising:
coupling a tunable non-Foster circuit between the receiver and the antenna, the receiver and the antenna having a combined reactance;
sensing the combined reactance of the tunable non-Foster circuit and the antenna in a sensing circuit; and
tuning the tunable non-Foster circuit to minimize the combined reactance of the tunable non-Foster circuit and the antenna as sensed by the sensing circuit.

18. A tunable non-Foster circuit comprising:
a conventional non-Foster circuit having an output where a negative capacitance is realized; and
a variable capacitor coupled in parallel with the output of the conventional non-Foster circuit where the negative capacitance is realized, the variable capacitor having a capacitance less than the absolute value of the negative capacitance realized by the conventional non-Foster circuit, so that a variable negative capacitance is realized across the output of the conventional non-Foster circuit by varying the variable capacitor.
